(19) United States
(12) Patent Application Publication
(10) Pub. No.: US 2011/0273805 A1
(43) Pub. Date: Nov. 10, 2011

(54) HDMI CABLE CONNECT APPARATUS AND METHOD

(76) Inventor: Don J. Nguyen, Portland, OR (US)

(21) Appl. No.: 12/775,272

(22) Filed: May 6, 2010

(51) Int. Cl. H02H 3/00; G01R 31/04

(52) U.S. Cl. 361/87; 324/538

(57) ABSTRACT

In some embodiments, an HDMI connection interface is provided with a connection detection circuit utilizing power cycling or an otherwise intermittent supply at a pin for an HDMI device for determining if the device is connected to an appliance.

### TECHNICAL FIELD

The present invention relates generally to a method and apparatus for detecting HDMI connectivity.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a diagram of a conventional HDMI connection status scheme.

FIG. 2 is a diagram of an HDMI connection status approach in accordance with some embodiments.

FIG. 3 is a schematic diagram of the HDMI connection status circuit of FIG. 2 in accordance with some embodiments.

FIG. 4 is a schematic diagram of an HDMI connection status circuit of FIG. 2 in accordance with additional embodiments.

### DETAILED DESCRIPTION

HDMI (High-Definition Multimedia Interface) is a compact audio/video interface for transmitting uncompressed digital data. Today's display devices such as monitors and televisions are typically equipped with an HDMI connection/interface for displaying video content from an attached appliance. Appliances, e.g., upstream devices such as notebook computers, set top boxes, or smart-phones, which may or may not have their own displays, may use HDMI connections to transfer or display their video content onto an HDMI device such as a monitor with a larger-sized or otherwise higher quality display.

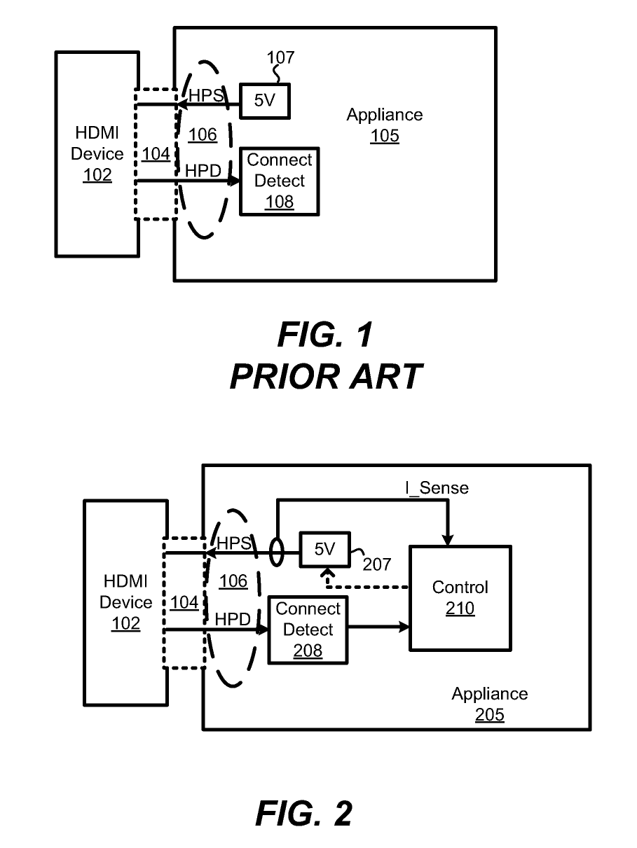

FIG. 1 generally shows an appliance 105 with an HDMI connection status feature for detecting whether the appliance is connected to a downstream HDMI device. The appliance 105 has an HDMI port 106 for connection to an HDMI device 102 through HDMI cable 104. It also includes a 5V source 107 and a connection detection circuit 108. With the current HDMI specification, upstream appliances (such as appliance 105) are to provide a DC supply (e.g., 5V supply) to a connected downstream device and detect connection to the device off of the supply, which when the device is connected, is returned back to the appliance 105 by way of a resistor (not shown) in the device 102.

Prior to an establishment of a valid HDMI connection, the upstream appliance needs to detect that the downstream device 102 has been mated with (e.g., plugged into) the upstream appliance. This is done via the Hot-Plug-Detect (HPD) pin in the HDMI connector, which is provided to the connection detection block 108. Thus, the upstream appliance 105 supplies the 5V supply to the HDMI cable before the HPD pin can be detected. In many conventional configurations, this can result in one or more different problems. For example, since the HDMI connector (or cable) for the appliance may be exposed to the external environment, a safety issue may be implicated if a pin is shorted via some external mechanism (e.g., malfunctioned cable shorting 5V supply pin to ground, etc.). In addition, keeping the 5 V supply enabled while “waiting” for a connection may waste excessive power, especially if the appliance is a portable device such as a smart phone, tablet, etc. Accordingly, in various embodiments disclosed herein, some or a combination of these, and possibly other, issues may be addressed.

FIG. 2 is a diagram showing an upstream appliance 205 with connection detection in accordance with some embodiments. It comprises a connection supply (5V) 207, a connection detection circuit 208 and a control unit 210, coupled as shown. In some embodiments, the appliance 205 may include a current sense (I_Sense) capability for monitoring current from the supply, when the device is connected, to ensure that excessive current is not being drawn.

In some embodiments, a connection detection scheme is provided whereby the connection supply 207 may be intermittently provided (e.g., pulsed, power cycled, or provided in a non-periodic intermittent manner) to the device 102 through a hot pin supply (HPS) pin. (Note that the term “pin” includes pin, contact, node or the like.) For example, a small duty cycle (e.g., On for a shorter time than Off) could be used to be supplied to the HPS pin. During the ON-time, the supply may be provided to the device 202, and the connection detection circuit 208 may be enabled to check for an appropriate signal returned through a hot pin detect (HPD) pin. For example, the ON time may be set to around 5 mS and the OFF time may be set to around 1000 mS.

During the ON-time, the control unit 210 may enable the supply (e.g., through a switch or by activating a regulator) to be provided to the HDMI device's supply input, which is coupled to the HPS pin. The HPD pin for the appliance may then be pulled up to a sufficient level (e.g., up to 5V), if the device is connected, thereby allowing the connection detection circuit 208 to read the sufficient HPD level and indicate that the device 102 is connected. On the other hand, during the OFF time, the supply and in some embodiments the connection detection circuit may be deactivated, e.g., to save power.

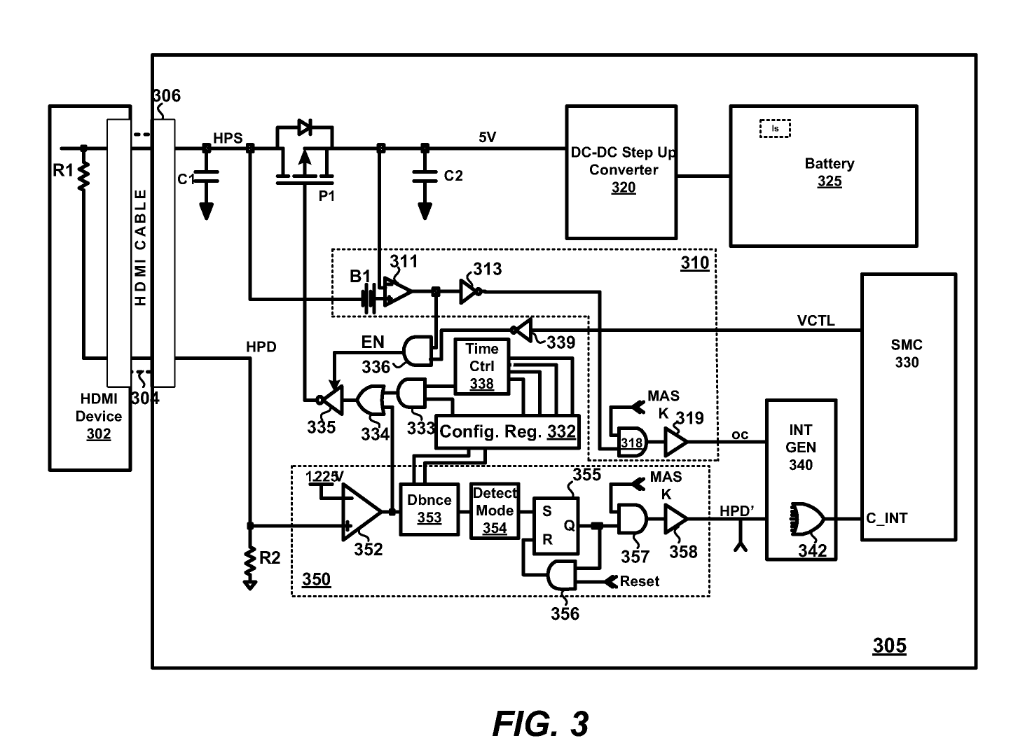

FIG. 3 shows an exemplary appliance with a connection detection circuit shown in greater detail in accordance with some embodiments. The appliance 305 is shown coupled through its HDMI port 306 to an HDMI device 302 by way of an HDMI cable 304. Port 306 comprises first (HPS) and second (HPD) pins coupled to corresponding pins in the cable 304 and in turn, to the HDMI device 302. (The link would typically include additional pins not shown for brevity sake.)

Appliance 305 generally comprises capacitors C1, C2, power MOS switch (PMOS) P1, over-current monitor section 310, step-up converter 320, battery 325, system management controller (SMC) 330 with associated control logic 332-338, interrupt circuit 340, and connection detection circuit 350. The controller (control unit or SMC controller in this example) 330, through control logic 332-338, controls the power switch P1 to provide a 5V supply to the down stream HDMI device 302. In this example, the 5V supply is generated by the step-up converter off of the battery supply 325 (e.g., a 3.0 to 4.2 V output voltage).

The current monitoring circuit 310 includes a comparator 311, voltage drop source B1, and logic gates 313, 318, and 319. The voltage drop source B1, for example, may be implemented with a current source pulling current through a resistor coupled between the non-inverting input of the comparator and the power MOS switch P1. The power switch has a suitably consistent and known resistance drop when turned on and thus, when sufficient current flows through the power switch P1 (i.e., enough to make the drop across the switch exceed the B1 drop), the inverting input goes above the non-inverting input, and the comparator de-asserts (outputs a Low in this depiction). On the other hand, when current through the power switch is not excessive, a High is provided out of the comparator 311.

(Note that in some embodiments, current monitoring may be implemented by way of current sense functionality, indicated in a dashed box as “Is”, within a utilized DC-DC converter, and thus, separate components such as with over-current circuit 310 may be omitted. In such implementations, the converter may provide to the controller a signal indicating a present current level, or it may provide a different suitable signal such as an interrupt, e.g., in response to an over-current condition. In some embodiments, current monitoring may not be employed.)

The connection detection circuit 350 comprises resistor R2, comparator 352, debounce circuit 353, detection mode circuit 354, RS flip-flop 355, and logic gates 356-358, coupled as shown. When the 5V supply is provided at the HPS pin to the device 302, the supply voltage is dropped across resistors R2 and R1, which imposes a smaller voltage at the HPD pin. The voltage level at the HPD pin corresponds to the product of the supply (5V) multiplied by the ratio of R1 to R1+R2. For example, if R2 is equal to R1, then a 2.5V level would be at the HPD pin when the device is connected to the appliance. The level at the HPD pin is compared by comparator 352 against the threshold (1.225V in this example) at the inverting input. If the HPD pin has a sufficient level (larger than the inverting input threshold level), then the comparator asserts (e.g., High).

The debounce circuit 353 performs conventional debounce filtering. Its debounce timing window may be set by configuration register 332. For example, as with the depicted embodiment, 2 bits may be used to allow it to be set to one of four available options (e.g., 0, 10, 20, or 30 mSec.). If an assertion (High) from the comparator is sustained past the debounce time window, then the debounce block 353 asserts (e.g., High) at the input of the detection mode circuit 354. The detection mode circuit (which may also be set, for example, through the configuration register, although no lines are shown) allows for positive to negative or negative to positive transitions to be detected from the debounce block 353. If an appropriate transition is detected from the debounce circuit, the flip-flop 355 sets. This causes a High to assert from its output, which causes the AND gate 357 to assert (High), assuming that the MASK signal (e.g., from the controller 330) is active. This causes the outputs of 357 and 358 to assert, which causes the interrupt generation block 340 to generate and interrupt to the controller 330 (at the C_INT input). In this depicted embodiment, the interrupt generator 340 comprises a NOR gate 342 (or equivalent) to receive a plurality of different interrupt signals from different appliance system functional units (e.g., to detect other peripheral links or connections such as a plugged in USB connection or available wireless network link). Accordingly, in the depicted embodiment, the controller is further coupled (not shown) to the connection detection block 350 to determine or confirm that the connection detection circuitry has asserted, indicating that an HDMI connection has occurred. Once determined, it resets the latch 355 via a “Reset” input at AND gate 356.

The control logic (332-338) comprises a configuration register 332, logic gates 333-336, and a timing control circuit 338, coupled as shown. In the depicted embodiment, the configuration register 332 is an 8-bit register, with 4 bits used to define supply ON and OFF times (e.g., two bits for 4 ON-time options and two bits for 4 OFF-time options), an enable bit provided to AND gate 333 to enable/disable the supply through AND gate 333, and 2 bits for the debounce circuit 353 to select the debounce window time. As mentioned above, another bit may be used to set the detection mode circuit 354.

In operation, assuming that the register 332 enables connection detection (via its direct bit link to AND gate 333), the time control block 338 causes the AND gate 333 to assert, which turns on MOS switch P1, for the ON time defined by the configuration register 332, and then turns it off for the prescribed OFF time. This pulse train power cycling repeats until an HDMI device is detected, as being connected, whereupon switch P1 is latched On to provide a stable, consistent 5V DC supply at the HPS pin to the HDMI device 302. (The On/Off power cycling may also cease when deactivated by the over current circuit or when otherwise disabled by the controller 330 through AND gate 336.) When an HDMI device is connected (and comparator 352 asserts), the switch (P1) is essentially latched on due to the output of comparator 352 also being connected to OR gate 334. At the same time, note that inverter 335 is enabled/disabled by the output of AND gate 336 so that the over current circuit 310 and the controller 330 are able to turn off the switch even when comparator 352 is asserting OR gate 334. In some embodiments, during power cycling Off-times, some or all connection detection circuitry (such as the comparator 352) can be turn off to reduce quiescent power consumption. For example, the timing control circuit 338 may be coupled to the connection detection circuitry to gate it on/off in synch. with the HPS signal.

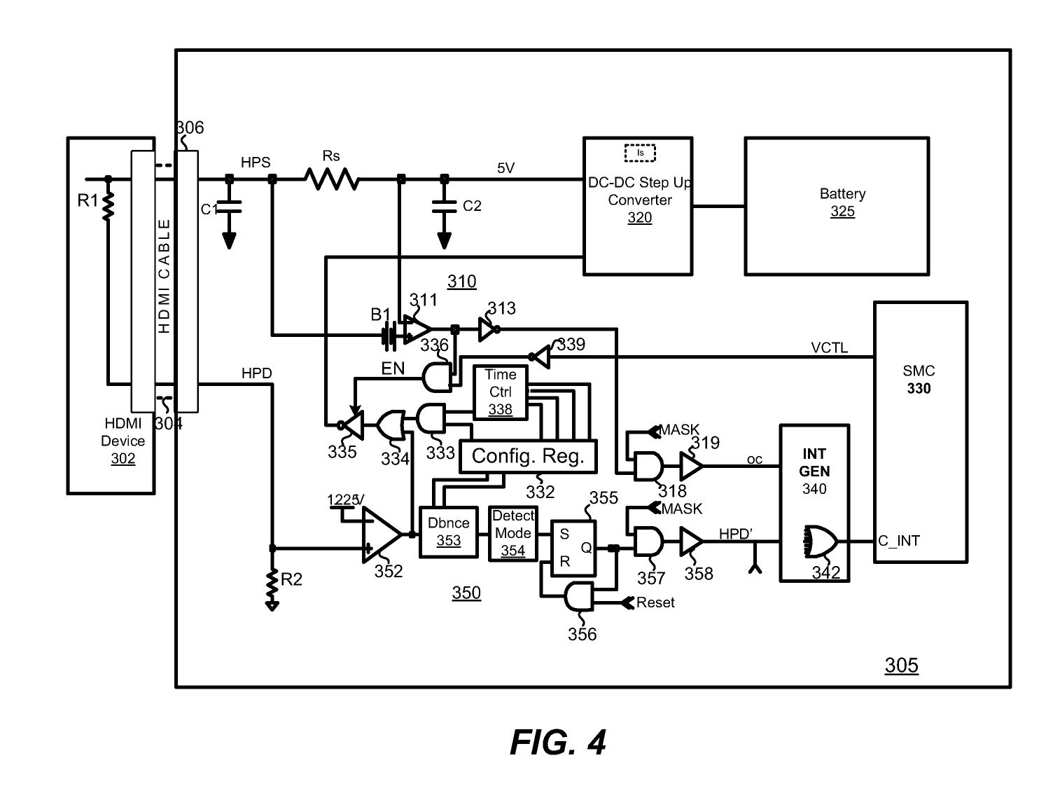

FIG. 4 shows another embodiment of circuitry for detecting an HDMI device being connected to an appliance. It is similar to the implementation of FIG. 3 except that in this embodiment, the power switch P1 is omitted and replaced with a current sensing resistor (Rs). The power cycling of the supply at the HPS pin is controlled by controlling the step-up converter 320 to output (On) or not output (Off) the HPS supply signal.

In the preceding description, numerous specific details have been set forth. However, it is understood that embodiments of the invention may be practiced without these specific details. In other instances, well-known circuits, structures and techniques may have not been shown in detail in order not to obscure an understanding of the description. With this in mind, references to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the preceding description and following claims, the following terms should be construed as follows: The terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, material types, insulator thicknesses, gate(s) configurations, to mention just a few. Moreover, unless specifically referred to as MOS or the like, the term transistor can include other suitable transistor types, e.g., junction-field-effect transistors, bipolar-junction transistors, metal semiconductor FETs, and various types of three dimensional transistors, MOS or otherwise, known today or not yet developed.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

It should also be appreciated that in some of the drawings, signal conductor lines are represented with lines. Some may be thicker, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS, for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. An apparatus, comprising:
a circuit to detect a connected HDMI device, said circuit to provide an intermittent supply to a connector to determine if the device is connected.

2. The apparatus of claim 1, in which the intermittent supply is a voltage pulse with a controllable duty cycle.

3. The apparatus of claim 2, in which the controllable duty cycle is less than 20 percent.

4. The apparatus of claim 2, in which the circuit comprises a programmable register with one or more bits for setting the duty cycle.

5. The apparatus of claim 1, in which the intermittent supply is a 5V DC supply when On.

6. The apparatus of claim 1, in which the circuit controls the intermittent supply be a steady DC supply when it is determined that an HDMI device is connected.

7. The apparatus of claim 5, in which the circuit comprises an over-current circuit to monitor current flowing from the DC supply.

8. The apparatus of claim 6, in which the DC supply is disengaged from the HDMI device when excessive current is detected.

9. The apparatus of claim 1, in which the circuit comprises a power switch to provide the intermittent supply.

10. The apparatus of claim 8, in which the switch is latched On when the HDMI device is detected.

11. A circuit, comprising:
a supply node in an appliance, the supply node to be coupled to a first pin of an external HDMI device;
a supply to provide a DC supply pulse to the supply node; and
a detection circuit to perceive the pulse from a second pin of the external HDMI device if the device is connected to the appliance.

12. The circuit of claim 11, in which the DC supply pulse has programmable On and Off times.

13. The circuit of claim 11, in which the detection circuit comprises a comparator to compare a voltage at the second pin against a threshold level.

14. The circuit of claim 11, comprising a switch to provide the DC supply pulse to the supply node.

15. The circuit of claim 14, in which the detection circuit latches the supply node to provide a DC supply when the device is connected.

16. A portable electronic appliance, comprising:
an HDMI connector having first and second pins, the first pin to provide an intermittent hot pin detect (HPD) signal to an HDMI device when connected to the appliance, the second pin to receive at least a form of the HPD signal back from the device when the device is connected to the appliance; and
a connection detection circuit coupled to the second pin to perceive the HPD signal form and to cause the intermittent HPD signal to be replaced by a DC supply when the device is detected to be connected to the appliance.

17. The appliance of claim 16, in which the intermittent HPD signal is a DC pulse with programmable On and Off times.

18. The appliance of claim 16, comprising an over current circuit to monitor current provided to the first pin.

19. The appliance of claim 16, in which the connection detection circuit comprises a latch to generate an interrupt to a controller when the device is determined to be connected.

20. The appliance of claim 16, in which the HDMI device is a monitor.
